(19) United States
(12) Patent Application Publication
(10) Pub. No.: US 2016/0155895 A1
(43) Pub. Date: Jun. 2, 2016

(54) Light-Emitting Diode Epitaxial Structure

(71) Applicant: TIANJIN SANAN OPTOELECTRONICS CO., LTD., Tianjin (CN)

(72) Inventors: LI-MING SHU, Tianjin (CN); DONG-YAN ZHANG, Tianjin (CN); XIAO-FENG LIU, Tianjin (CN); ZHI-BIN LIU, Tianjin (CN); LIANG-JUN WANG, Tianjin (CN); DU-XIANG WANG, Tianjin (CN)

(73) Assignee: TIANJIN SANAN OPTOELECTRONICS CO., LTD., Tianjin (CN)

(21) Appl. No.: 14/750,286

(22) Filed: Jun. 25, 2015

(30) Foreign Application Priority Data
Nov. 27, 2014 (CN) 201410695201.8

(51) Int. Cl. H01L 33/06; H01L 33/12; H01L 33/32; H01L 33/00; H01L 33/24

(52) U.S. Cl. CPC H01L 33/06; H01L 33/0025; H01L 33/24; H01L 33/32; H01L 33/325; H01L 33/12

(57) ABSTRACT

An epitaxial wafer structure of light-emitting diode includes, from bottom to up, a substrate, an N-type GaN layer, a MQW light-emitting layer and a P-type GaN layer, in which, at least one In_{y}Ga_{1-y}N/AlN composition layer (0<y≦1) is inserted in the N-type GaN and at least one multi-layer AlN/In_{z}Ga_{1-z}N composition layer (0<z≦1) is inserted in the P-type GaN layer; and AlN part in the inserting layer increases barrier to form a blocking layer and the In_{y}Ga_{1-y}N layer reduces barrier to form a carrier capture layer so as to generate two-dimensional electron gas of higher concentration and more-concentrated distribution in the N-type GaN layer and the P-type GaN layer, thereby improving current spreading capacity.

### CROSS-REFERENCE TO RELATED APPLICATIONS

The present application is a continuation of and claims priority to Chinese Patent Application No. CN 201410695201.8 filed on Nov. 27, 2014, the disclosure of which is hereby incorporated by reference in its entirety.

### BACKGROUND

Light-emitting diode (LED) is a semiconductor light-emitting device, taking semiconductor P-N junction as the light-emitting structure. In recent years, the third-generation wide band-gap semiconductor material represented by GaN attracts wide concern and much study in the industry, which achieves great advantages in large-power electronic device field and breakthroughs in recent years.

Epitaxial structure is a key technology in large-power LED fabrication. In general, P-N structure is adopted and a multiple quantum-well (MQW) light-emitting layer is set between the P-type semiconductor layer and the N-type semiconductor layer. However, as the chip gets larger, current blocking becomes increasingly apparent, thus imposing higher requirements for light-emitting uniformity and anti-static capacity of the chip.

SUMMARY

The present disclosure provides an epitaxial wafer structure of light-emitting diode with high-efficiency two-dimensional electron gas, and the main technical scheme is that: 1) take heat treatment for the substrate with hydrogen or with mixed gas of hydrogen, nitrogen and ammonia gas. 2) grow a low-temperature AlₓGa₁₋ₓN (0≦x≦1) buffer layer, an undoped GaN layer, an N-type GaN layer, a MQW light-emitting layer and a P-type GaN layer over the substrate after heat treatment. 3) during growth of the N-type GaN, at least one In_{y}Ga_{1-y}N/AlN composition layer (0<y≦1) is inserted, and during growth of the P-type GaN layer, at least one AlN/In_{z}Ga_{1-z}N composition layer (0<z≦1) is inserted.

Further, in the In_{y}Ga_{1-y}N/AlN composition layers at different positions of the N-type GaN layer and the AlN/In_{z}Ga_{1-z}N composition layers at different positions of the P-type GaN layer, the In concentrations keep stable (i.e., y and z keep stable) or appear linear increase or decrease, or in zigzag, rectangle, Gaussian distribution or stair-step distribution.

Further, in the In_{y}Ga_{1-y}N/AlN composition layers at different positions of the N-type GaN layer and the AlN/In_{z}Ga_{1-z}N composition layers at different positions of the P-type GaN layer, the In concentrations are controlled by temperature or TMIn amount.

Further, in the In_{y}Ga_{1-y}N/AlN composition layers at different positions of the N-type GaN layer and the AlN/In_{z}Ga_{1-z}N composition layers at different positions of the P-type GaN layer, the InGaN or AlN thicknesses keep stable or appear linear increase or decrease, or in zigzag, rectangle, Gaussian distribution or stair-step distribution.

Further, in the In_{y}Ga_{1-y}N/AlN composition layers of the N-type GaN layer and the AlN/In_{z}Ga_{1-z}N composition layers of the P-type GaN layer, the AlN inserting layer can be replaced with AlGaN, AlInGaN or AlInN.

Further, in same sublayer or among different sublayers isolated by the In_{y}Ga_{1-y}N/AlN composition layer of the N-type GaN layer, Si doping concentrations keep stable or appear linear increase or decrease, or in zigzag, rectangle, Gaussian distribution or stair-step distribution.

Further, in same sublayer or among different sublayers isolated by the AlN/In_{z}Ga_{1-z}N composition layer of the P-type GaN layer, Mg doping concentrations keep stable or appear linear increase or decrease, or in zigzag, rectangle, Gaussian distribution or stair-step distribution.

The present disclosure provides an epitaxial wafer structure of light-emitting diode with high-efficiency two-dimensional electron gas, in which, during growth of the N-type GaN, a plurality of In_{y}Ga_{1-y}N/AlN composition layers (0<y≦1) are inserted, and during growth of the P-type GaN layer, a plurality of AlN/In_{z}Ga_{1-z}N composition layers (0<z≦1) are inserted; and MN part in the composition layer increases barrier to form a carrier blocking layer and the In_{y}Ga_{1-y}N layer reduces barrier to form a carrier capture layer so as to generate two-dimensional electron gas of higher concentration and more-concentrated distribution in the N-type GaN layer and the P-type GaN layer.

In this disclosure, different materials have different band gaps. In the N-type GaN layer and the P-type GaN layer, form a high barrier blocking layer and a carrier capture layer respectively at the same time. Under same doping concentration, the formed two-dimensional electron gas has higher concentration and more-concentrated distribution to improve current spreading capacity. The LED epitaxial structures can be applied to light-emitting systems such as display systems or lighting systems, where a plurality of LEDs are included.

### BRIEF DESCRIPTION OF THE DRAWINGS

FIG. 1 is a schematic diagram of the epitaxial layer of light-emitting diode of the present disclosure.

FIG. 2 is an enlarged view of the N-type GaN layer 4 structure as shown in FIG. 1.

FIG. 3 is an enlarged view of the P-type GaN layer 6 structure as shown in FIG. 1.

FIG. 4 is a schematic diagram of two-dimensional electron gas in the N-type GaN and the P-type GaN layer of the present disclosure.

In the drawings: 1: substrate, 2: low-temperature GaN buffer layer, 3: undoped GaN layer, 4: N-type GaN layer, 5: MQW light-emitting layer, 6: P-type GaN layer, in which, A₁-Aₙ: In_{y}Ga_{1-y}N inserting layer in the N-type GaN layer, B₁-Bₙ: AlN inserting layer in the N-type GaN layer, C₁-Cₙ: In_{z}Ga_{1-z}N inserting layer in the P-type GaN layer and D₁-Dₙ: AlN inserting layer.

### DETAILED DESCRIPTION

### Embodiments

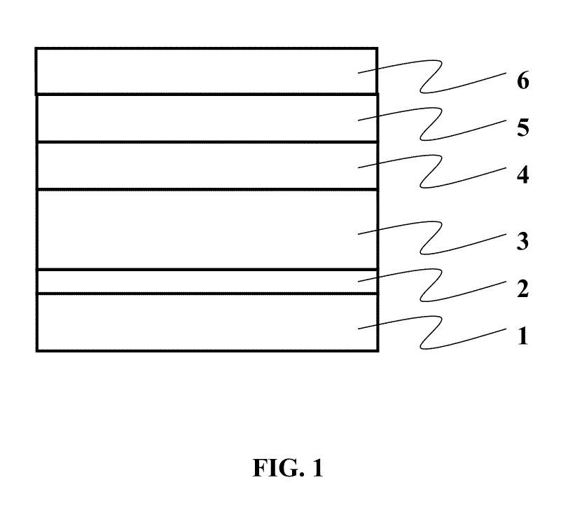

FIG. 1 is the structural diagram of the epitaxial wafer structure of light-emitting diode with high-efficiency two-dimensional electron gas, comprising from bottom to up: (1) a sapphire substrate 1; (2) an AlₓGa₁₋ₓN buffer layer 2, made of GaN, AlN, AlGaN or their combination with film thickness of 10-100 nm; (3) an undoped GaN layer 3 with thickness of 500-5000 nm, and preferably 1500 nm; (4) an N-type GaN layer 4, in which, In_{y}Ga_{1-y}N/AlN composition layers are formed in the N-type GaN layer, (5) a MQW light-emitting layer 5, in which, InGaN is the well layer, and GaN, AlGaN or their combination as the cladding layer; the cladding layer is about 50-150 nm thick and the well layer is about 1-20 nm thick, a plurality of cycle structures are formed to form an active region; (6) a P-type GaN layer 6 with film thickness of 20 nm-2000 nm, and preferably 200 nm; (7) and AlN/In_{z}Ga_{1-z}N composition layers grown in the P-type GaN layer.

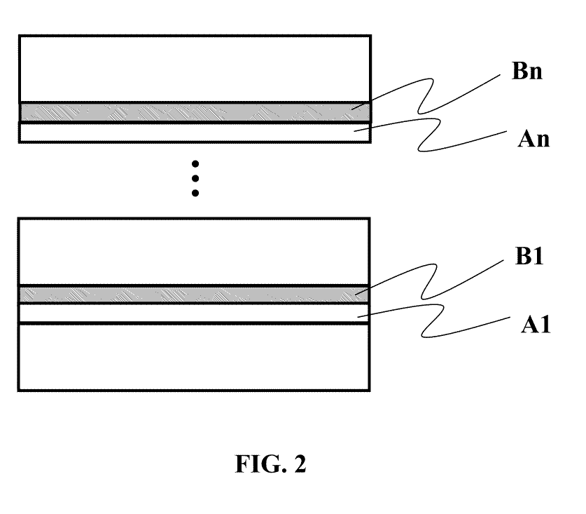

FIG. 2 is a structural diagram of the N-type GaN layer 4 in epitaxial wafer of light-emitting diode. A multi-layer In_{y}Ga_{1-y}N/AlN composition structure is inserted in the N-type GaN layer, in which, A₁-Aₙ is an In_{y}Ga_{1-y}N and serves as an electron capture layer, and In components in the InGaN can be controlled by In flow or/and temperature, and preferably, flow control is adopted; the inserting layer is about 10-50 nm thick, in which, in 0<y≦1, preferably, n is 5-20; AlN is the electron blocking layer, with growth condition same as that of the N-type GaN and prefer thickness is 5-25 nm.

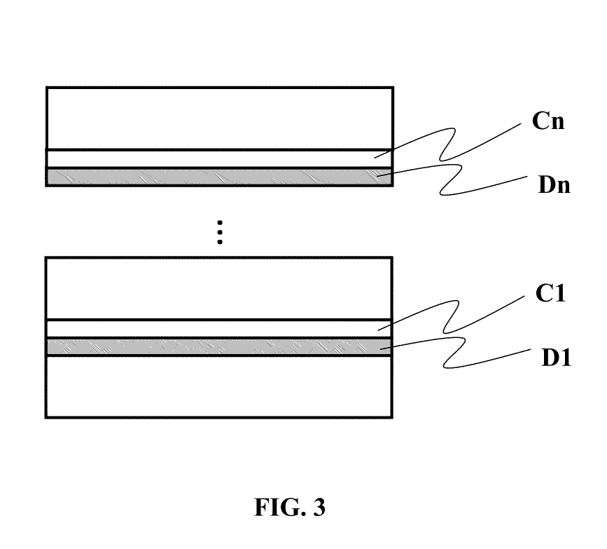

FIG. 3 is a structural diagram of the P-type GaN layer 5 in epitaxial wafer of light-emitting diode. A plurality of AlN/In_{z}Ga_{1-z}N composition layers are inserted in the P-type GaN layer, in which, D₁-Dₙ is the In_{z}Ga_{1-z}N layer of the P-type GaN layer and serves as the hole capture layer, and In components in the InGaN can be controlled by In flow or/and temperature, and preferably, flow control is adopted; the inserting layer is about 10-50 nm thick, in which, n is 5-20; AlN is the electron blocking layer, with growth condition same as that of the P-type GaN and prefer thickness is 5-25 nm.

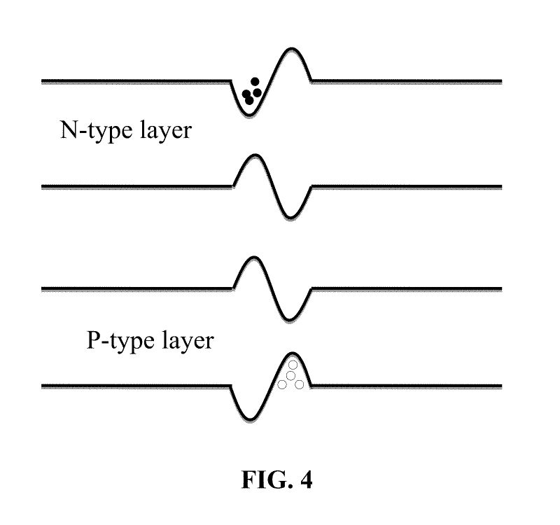

As a specific embodiment of present disclosure, as band gap width of InGaN material is less than that of GaN, and band gap width of AlN material is larger than that of the GaN material. By taking advantages of such feature, In_{y}Ga_{1-y}N/AlN and AlN/In_{z}Ga_{1-z}N composition structures are inserted in the N-type GaN layer and the P-type GaN layer respectively and the composition structures are used to form a carrier capture layer and a blocking layer to form two-dimensional electron gas of higher concentration and concentrated distribution, as shown in FIG. 4, thus significantly improving current spreading and inverse anti-statistic capacity.

As a first alternating embodiment of this embodiment, among different sublayers separated by the inserting composition layer in the N-type GaN layer, the Si-doping concentration appears gradient increase, and among different sublayers separated by the inserting composition layer in the P-type GaN layer, Mg-doping concentration appears gradual decrease to form two-dimensional electron gas of high concentration approximate to the MQW light-emitting layer, thus improving performance.

As a second alternating embodiment of this embodiment, at the same sublayer separated by the inserting composition layer in the N-type GaN layer, Si-doping concentration appears gradual increase from the previous inserting layer to the next inserting layer; and at the same sublayer separated by the inserting composition layer in the P-type GaN layer, Mg-doping concentration appears gradual decrease from the previous inserting layer to the next inserting layer to obtain higher doping concentration approximate to the carrier capture layer, thus further improving two-dimensional electron gas concentration.

As a third alternating embodiment of this embodiment, the electron blocking layer in the N-type GaN and the P-type GaN layer can be replaced by AlGaN layer; and lattice mismatch between the inserting layer and the GaN layer can be reduced by optimizing the Al components in the AlGaN electron blocking layer so as to improve material quality.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. An epitaxial structure of a light-emitting diode (LED), comprising: a substrate, an N-type GaN layer, a MQW light-emitting layer and a P-type GaN layer, wherein at least one In_{y}Ga_{1-y}N/AlN composition layer (0<y≦1) is inserted in the N-type GaN layer and at least one AlN/In_{z}Ga_{1-z}N composition layer (0<z≦1) is inserted in the P-type GaN layer.

2. The epitaxial structure of claim 1, wherein the MN in the composition layer is adjacent to the MQW light-emitting layer.

3. The epitaxial structure of claim 1, wherein number of In_{y}Ga_{1-y}N/AlN composition layers (0<y≦1) inserted in the N-type GaN layer is 5-20; and number of AlN/In_{z}Ga_{1-z}N composition layers (0<z≦1) inserted in the P-type GaN layer is 5-20.

4. The epitaxial structure of claim 1, wherein an AlₓGa₁₋ₓN (0≦x≦1) buffer layer or/and undoped GaN layer is arranged between the substrate and the N-type GaN layer.

5. The epitaxial structure of claim 1, wherein in the In_{y}Ga_{1-y}N/AlN composition layers at different positions of the N-type GaN layer, and the AlN/In_{z}Ga_{1-z}N composition layers at different positions of the P-type GaN layer, In concentrations are constant (i.e., y and z are constants) or have a linear increase or decrease, or in a zigzag, a rectangle, a Gaussian, or a stair-step distribution.

6. The epitaxial structure of claim 5, wherein the In concentration is controlled by a temperature or/and TMIn amount.

7. The epitaxial structure of claim 1, wherein an InGaN or AlN thickness in the composition layer is constant or has a linear increase or decrease, or a zigzag, a rectangle, a Gaussian, or a stair-step distribution.

8. The epitaxial structure of claim 1, wherein in In_{y}Ga_{1-y}N/AlN composition layers of the N-type GaN layer and the AlN/In_{z}Ga_{1-z}N composition layers of the P-type GaN layer, the MN insertion layer is replaced with AlGaN, AlInGaN or AlInN.

9. The epitaxial structure of claim 1, wherein in same sublayer or among different sublayers isolated by the In_{y}Ga_{1-y}N/AlN composition layer of the N-type GaN layer, Si doping concentrations are constant or have a linear increase or decrease, or a zigzag, a rectangle, a Gaussian, or a stair-step distribution.

10. The epitaxial structure of claim 1, wherein in same sublayer or among different sublayers isolated by the AlN/In_{z}Ga_{1-z}N composition layer of the P-type GaN layer, Mg doping concentrations are constant or have a linear increase or decrease, or a zigzag, a rectangle, a Gaussian, or a stair-step distribution.

11. A light-emitting system including a plurality of light-emitting diodes (LEDs), each LED having an epitaxial structure comprising: a substrate, an N-type GaN layer, a MQW light-emitting layer and a P-type GaN layer, wherein at least one In_{y}Ga_{1-y}N/AlN composition layer (0<y≦1) is inserted in the N-type GaN layer and at least one AlN/In_{z}Ga_{1-z}N composition layer (0<z≦1) is inserted in the P-type GaN layer.

12. The system of claim 11, wherein the AlN in the composition layer is adjacent to the MQW light-emitting layer.

13. The system of claim 11, wherein number of In_{y}Ga_{1-y}N/AlN composition layers (0<y≦1) inserted in the N-type GaN layer is 5-20; and number of AlN/In_{z}Ga_{1-z}N composition layers (0<z≦1) inserted in the P-type GaN layer is 5-20.

14. The system of claim 11, wherein an AlₓGa₁₋ₓN (0≦x≦1) buffer layer or/and undoped GaN layer is arranged between the substrate and the N-type GaN layer.

15. The system of claim 11, wherein in the In_{y}Ga_{1-y}N/AlN composition layers at different positions of the N-type GaN layer, and the AlN/In_{z}Ga_{1-z}N composition layers at different positions of the P-type GaN layer, In concentrations are constant (i.e., y and z are constants) or have a linear increase or decrease, or in a zigzag, a rectangle, a Gaussian, or a stair-step distribution.

16. The system of claim 15, wherein the In concentration is controlled by a temperature or/and TMIn amount.

17. The system of claim 11, wherein an InGaN or AlN thickness in the composition layer is constant or has a linear increase or decrease, or a zigzag, a rectangle, a Gaussian, or a stair-step distribution.

18. The system of claim 11, wherein in In_{y}Ga_{1-y}N/AlN composition layers of the N-type GaN layer and the AlN/In_{z}Ga_{1-z}N composition layers of the P-type GaN layer, the AlN insertion layer is replaced with AlGaN, AlInGaN or AlInN.

19. The system of claim 11, wherein in same sublayer or among different sublayers isolated by the In_{y}Ga_{1-y}N/AlN composition layer of the N-type GaN layer, Si doping concentrations are constant or have a linear increase or decrease, or a zigzag, a rectangle, a Gaussian, or a stair-step distribution.

20. The system of claim 11, wherein in same sublayer or among different sublayers isolated by the AlN/In_{z}Ga_{1-z}N composition layer of the P-type GaN layer, Mg doping concentrations are constant or have a linear increase or decrease, or a zigzag, a rectangle, a Gaussian, or a stair-step distribution.
